(19) United States
(12) Patent Application Publication
(10) Pub. No.: US 2025/0163612 A1
(43) Pub. Date: May 22, 2025

(54) OVENS FOR NONLINEAR OPTICAL CRYSTALS AND METHOD OF USE

(71) Applicant: IPG Photonics Corporation, Oxford, MA (US)

(72) Inventors: Alex YUSIM, Oxford, MA (US); Bruce JENKET, Oxford, MA (US); Pancho TZANKOV, Oxford, MA (US)

(21) Appl. No.: 19/033,065

(22) Filed: Jan. 21, 2025

Related U.S. Application Data
(63) Continuation of application No. PCT/US2022/037904, filed on Jul. 21, 2022.

(51) Int. Cl. C30B 33/02; G02F 1/35; G02F 1/355

(52) U.S. Cl. CPC C30B 33/02; G02F 1/353; G02F 1/3551

(57) ABSTRACT

A system for wavelength conversion. In certain example an oven for a nonlinear optical (NLO) crystal includes a thermally conductive enclosure configured to define an opening for holding the NLO crystal and to thermally conduct heat between a heating element and the NLO crystal, the thermally conductive enclosure in thermal contact with at least a portion of the NLO crystal and the heating element configured to heat to a temperature of at least 250° C. inclusive, a support structure configured to support the thermally conductive enclosure, the support structure thermally isolated from the thermally conductive enclosure, and an expandable attachment assembly configured such that the NLO crystal is secured within the opening of the thermally conductive enclosure by a spring force exerted by the expandable attachment assembly.

### BACKGROUND

### Technical Field

The technical field relates generally to frequency conversion using nonlinear optical (NLO) crystals, and more specifically to ovens and their use for heating NLO crystals during frequency conversion processes.

### Background Discussion

Most laser sources emit at wavelengths only in the infrared, and therefore nonlinear optical effects are used to achieve wavelengths in the visible or ultraviolet (UV). For example, an infrared laser beam generated by a laser source (a pump beam) can be doubled in frequency by interaction with an NLO crystal (second harmonic generation), or two separate pump beams can be combined in an NLO crystal to generate a third beam whose frequency is equal to the sum of the frequencies of the incident beams (sum frequency generation). The range of wavelengths that can be created using these techniques spans from 150 nanometers (nm) to 20 microns (μm), and the laser light created can be continuous wave (CW) or pulsed and used in a wide range of applications, including applications that target material processing, biomedical, scientific, and consumer markets.

Currently available NLO crystal materials are designed to operate below 220° C. and for most applications, this upper limit is sufficient. However, for some specific applications there is a need for NLO crystal materials to operate at temperatures that are above this maximum.

### SUMMARY

Aspects and embodiments are directed to a method and system for nonlinear frequency conversion.

In accordance with one example, there is provided an oven for a nonlinear optical (NLO) crystal. The oven can include a thermally conductive enclosure configured to define an opening for holding the NLO crystal and to thermally conduct heat between a heating element and the NLO crystal, the thermally conductive enclosure in thermal contact with at least a portion of the NLO crystal and the heating element configured to heat to a temperature of at least 250° C. inclusive, a support structure configured to support the thermally conductive enclosure, the support structure thermally isolated from the thermally conductive enclosure, and an expandable attachment assembly configured such that the NLO crystal is secured within the opening of the thermally conductive enclosure by a spring force exerted by the expandable attachment assembly.

In an example, an air space at least partially extends between the thermally conductive enclosure and the support structure. In a further example, the support structure includes a recess for a spring of the expandable attachment assembly. In a further example, the oven further includes at least one thermally insulative device positioned between the support structure and the thermally conductive enclosure. In another example, the thermally conductive enclosure is configured to thermally conduct heat between the NLO crystal and two heating elements, and the oven further comprises a thermal sink extending between the thermally conductive enclosure and the support structure.

In an example, the heating element is configured to heat to a temperature of at least 400° C. inclusive.

In an example, the heating element is configured to heat to a temperature in a range of 250° C. to 500° C. inclusive.

In an example, the thermally conductive enclosure is constructed from a material that has a coefficient of thermal expansion that is different from a coefficient of thermal expansion of the NLO crystal, and the expandable attachment assembly is configured to reduce stress on the NLO crystal that occurs due to the difference in the coefficients of thermal expansion when the heating element heats to a temperature in a range of 250° C. to 500° C. inclusive.

In an example, the oven further includes a controller, the controller coupled to the heating element and configured to control an amount of heat produced by the heating element and to receive temperature measurements from a temperature sensor positioned in proximity to the NLO crystal.

In an example, the thermally conductive enclosure is constructed from aluminum.

In an example, the thermally conductive enclosure includes at least two components and is configured such that a gap exists between a first and a second component that are adjacent one another.

In an example, the oven is configured to operate without a thermal enclosure.

In an example, the NLO crystal is configured for non-critical phase matching at a temperature in a range of 250° C. to 500° C. inclusive.

In an example, a method includes providing an oven as described in claim 1.

In accordance with another example, a wavelength conversion method is provided. The method can include providing a laser light source configured to generate a laser light beam having a first wavelength, providing an oven for a nonlinear optical (NLO) crystal, the oven including a thermally conductive enclosure configured to define an opening for holding the NLO crystal and to thermally conduct heat between a heating element and the NLO crystal, and a support structure configured to support the thermally conductive enclosure, the support structure thermally isolated from the thermally conductive enclosure, positioning the NLO crystal within the opening of the oven, heating the nonlinear optical (NLO) crystal to a temperature of at least 250° C. inclusive, the NLO crystal configured to convert the first wavelength to at least one second wavelength, and directing the laser light beam through the NLO crystal.

In an example, heating includes heating the NLO crystal to a temperature in a range of 250° C. to 500° C. inclusive.

In an example, the method further includes providing the NLO crystal.

In a further example, nonlinear frequency mixing occurs between different modes of the laser light beam having the first wavelength within the NLO crystal, and the nonlinear frequency mixing is a mixing operation selected from the group consisting of harmonic generation, sum frequency generation, difference frequency generation, optical parametric generation, optical parametric amplification, and optical parametric oscillation.

In an example, the method further includes measuring a temperature of the NLO crystal and controlling the heating element based on the temperature measurement.

In an example, the oven further includes an expandable attachment assembly configured such that the NLO crystal is secured within the opening of the thermally conductive enclosure by a spring force exerted by the expandable attachment assembly.

Still other aspects, embodiments, and advantages of these example aspects and embodiments, are discussed in detail below. Moreover, it is to be understood that both the foregoing information and the following detailed description are merely illustrative examples of various aspects and embodiments, and are intended to provide an overview or framework for understanding the nature and character of the claimed aspects and embodiments.

Embodiments disclosed herein may be combined with other embodiments, and references to “an embodiment,” “an example,” “some embodiments,” “some examples,” “an alternate embodiment,” “various embodiments,” “one embodiment,” “at least one embodiment,” “this and other embodiments,” “certain embodiments,” or the like are not necessarily mutually exclusive and are intended to indicate that a particular feature, structure, or characteristic described may be included in at least one embodiment. The appearances of such terms herein are not necessarily all referring to the same embodiment.

### BRIEF DESCRIPTION OF DRAWINGS

Various aspects of at least one embodiment are discussed below with reference to the accompanying figures, which are not intended to be drawn to scale. The figures are included to provide an illustration and a further understanding of the various aspects and embodiments, and are incorporated in and constitute a part of this specification, but are not intended as a definition of the limits of any particular embodiment. The drawings, together with the remainder of the specification, serve to explain principles and operations of the described and claimed aspects and embodiments. In the figures, each identical or nearly identical component that is illustrated in various figures is represented by a like numeral. For purposes of clarity, not every component may be labeled in every figure. In the figures:

FIGS. 1A and 1B are simplified schematic representations of one example of an NLO oven enclosure and heater taken along the optical axis and longitudinal axis of the NLO crystal, respectively, in accordance with one or more aspects of the invention;

FIG. 1C is a perspective view of an NLO crystal in accordance with one or more aspects of the invention;

FIGS. 2A and 2B are simplified schematic representations of another example of an NLO oven enclosure and heater taken along the optical axis and longitudinal axis of the NLO crystal, respectively, in accordance with one or more aspects of the invention;

FIG. 3 is a simplified schematic representation of one example of a support plate and expandable attachment assembly that may be used with an NLO oven configuration in accordance with aspects of the invention;

FIG. 4 is a simplified schematic representation of an example of a thermal separation device that may be used with an NLO oven configuration in accordance with aspects of the invention;

FIG. 5 is a simplified schematic representation of another example of a support plate and expandable attachment assembly that may be used with an NLO oven configuration in accordance with aspects of the invention;

FIG. 6 is a block diagram of an NLO oven system in accordance with aspects of the invention;

FIG. 7 is a simplified block diagram of a wavelength conversion system in accordance with aspects of the invention;

FIG. 8 is a graph showing an example of the relationship between UV laser pulse energy and a temperature gradient across an NLO crystal in accordance with aspects of the invention; and

FIG. 9 is a graph showing an example of the relationship between green laser power, conversion efficiency, and a temperature gradient across an NLO crystal in accordance with aspects of the invention.

### DETAILED DESCRIPTION

As previously mentioned, currently available NLO crystal materials are designed to operate at temperatures below 220° C. However, for some specific applications there is a need for NLO crystal materials to operate at temperatures that are above 220° C.

One non-limiting example of such an application includes the generation of wavelengths that are shorter than 600 nm. As the average or peak power of the incoming laser beam increases, multiple photons can be absorbed by the NLO crystal material, which damages the crystal material and introduces defects such as color centers that lead to degradation. Furthermore, as the wavelength further decreases to the ultraviolet (UV) and deep ultraviolet (DUV) wavelength ranges, two-photon absorption becomes a key issue in conversion efficiency and power degradation.

Conventional approaches for addressing these problems include increasing the temperature of the NLO crystal, which reduces two-photon absorption and improves the operating lifetime of the system. In addition, higher temperatures destroy contaminants that can potentially create surface damage.

A second non-limiting example of an application that could benefit from NLO crystal materials operated at temperatures above 220° C. is in applications that introduce variable or tunable time delays between different wavelengths. Frequency conversion for pulsed light requires that the mixed light be overlapped spatially and temporally in the crystal. Temporal overlap can be adjusted when two wavelengths of light are orthogonal in polarization within the NLO crystal. The crystals can be designed with proper cut angles and lengths to overlap the pulses in time. However, as the optical power changes, the pulse overlap can also change due to thermal changes of the refractive index, which reduces the conversion efficiency. The temporal overlap can be corrected by operating the crystal at a different temperature. Having the ability to operate the NLO crystal in a wider range of temperatures permits temporal overlap over a wide range of output powers.

Yet another non-limiting example of an application that could benefit from a higher operating temperature for the NLO crystal involves phase matching. NLO crystals are cut at specific angles such that there is phase matching between different wavelengths for a specific temperature. Without this phase matching, the nonlinear conversion is quite weak and in some instances so low as to render the device unusable. In addition, it is possible that a phase matching condition does not exist in some crystals. Increasing the upper temperature range of the crystals increases the feasibility of using crystal materials that are difficult to phase match.

One or more aspects of the invention address the aforementioned and other potential applications by providing a system and a wavelength conversion method that includes heating the NLO crystals to a temperature of at least 250° C. inclusive, and encompasses embodiments where the temperatures are as high as 500° C.

It is anticipated that for certain UV generation applications, the value of the two-photon absorption coefficient β (cm/GW) at 250-500° C. will be at least four times lower than that at room temperatures. In addition, the long-term power stability for this generation is expected to improve at these higher temperatures as compared to room temperatures.

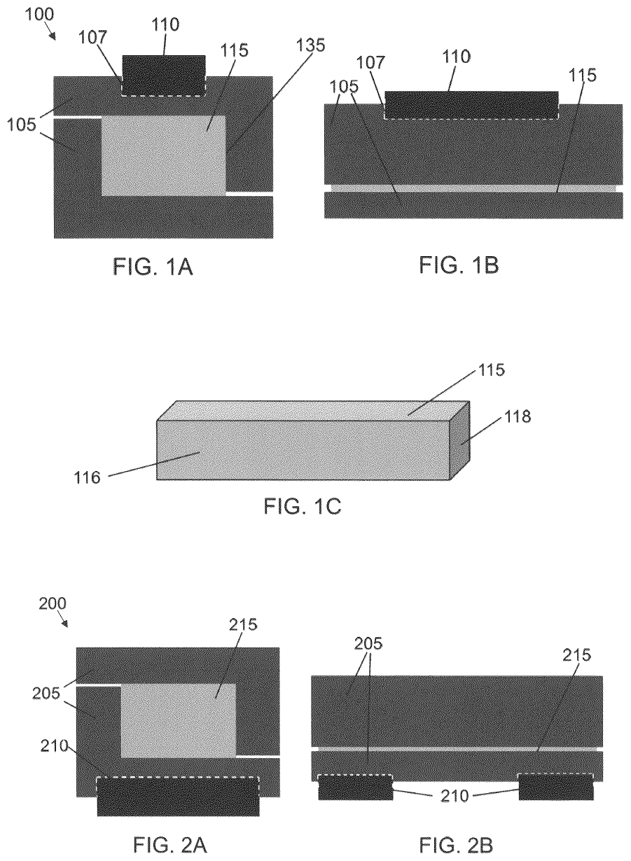

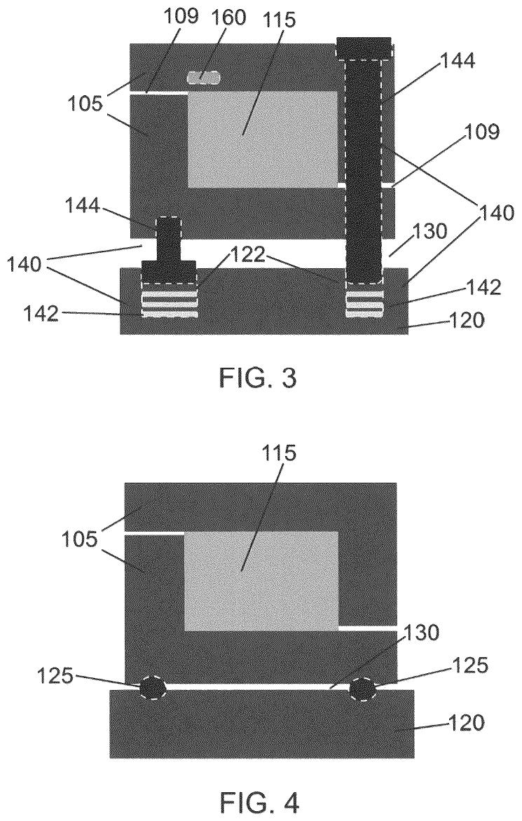

In accordance with at least one embodiment, FIGS. 1A and 1B are simplified schematic representations of one non-limiting example of an NLO oven (labeled generally at 100, also referred to herein as simply “oven”) showing an end view of the optical axis and a side view of the longitudinal axis of the NLO crystal 115, respectively. A perspective view of an NLO crystal 115 is shown in FIG. 1C, where the longitudinal face 116 (corresponding to the longitudinal axis) and end face 118 (corresponding to the optical axis) are illustrated. The oven 100 comprises a thermally conductive enclosure 105 for housing the NLO crystal 115, a support structure 120 (an example is shown in FIGS. 3 and 4), and an expandable attachment assembly 140 (an example is shown in FIGS. 3 and 4).

The thermally conductive enclosure 105 is configured to define an opening 135 for holding the NLO crystal 115 and is in thermal contact with at least a portion of the NLO crystal 115. The thermally conductive enclosure 105 is configured to thermally conduct heat between a heating element 110 and the NLO crystal 115. The heating element 110 is configured to heat to a temperature of at least 250° C. inclusive, as discussed in further detail below.

In accordance with at least one embodiment, the thermally conductive enclosure 105 (also referred to herein as simply “enclosure”) is constructed from a thermally conductive material, such as metals. In one embodiment, the thermally conductive material is aluminum, such as 6061 T6 aluminum. The thermally conductive material can be any material that is capable of performing the structural requirements of holding the crystal 115 without damage and capable of withstanding or otherwise not being detrimentally affected by the desired operating temperatures, e.g., temperatures in a range of 250-500° C. In some embodiments, the enclosure 105 is constructed from stainless steel. According to one embodiment, the support structure 120 (described in more detail below) can also be constructed from the same materials as the thermally conductive enclosure 105.

In certain embodiments, the thermally conductive enclosure 105 includes at least two components. The example shown in FIGS. 1A and 1B has two L-shaped components that form the opening 135 for the NLO crystal 115. It is to be appreciated that other configurations are within the scope of this disclosure. In some embodiments, the thermally conductive enclosure 105 is configured such that a gap 109 exists between first and second components that are adjacent one another (e.g., see FIG. 3). This gap 109 functions to allow for the NLO crystal 115 to expand when heated by the laser beam. In some embodiments, this gap 109 and the spring force configuration provided by the expandable attachment assembly 140 allow for components of the thermally conductive enclosure 105 to expand (and contract) in a direction running perpendicular to the optical axis. As shown in FIGS. 1A, 3, and 4 (and also present in FIG. 2A) a component of the thermally conductive enclosure 105 (e.g., a length, height, and/or width (interior) dimension) is sized to be smaller than the corresponding dimension of the NLO crystal 115, which allows for the gap 109. It is to be appreciated that in some embodiments the thermally conductive enclosure 105 may include an adapter for smaller or differently shaped crystals that functions to hold the crystal 115.

The NLO crystal 115 can be a single crystal of any one of a number of nonlinear optical materials and can have various dimensions and orientations. It is to be appreciated that these choices are application-specific. As will be appreciated, the NLO crystal 115 is configured to convert a first wavelength, e.g., from a laser light source, to at least one second wavelength. According to some embodiments, the NLO crystal 115 is one of a doubling crystal, a frequency mixing crystal, and an optical parametric crystal.

Non-limiting examples of crystal materials include lithium triborate (LBO), β-barium borate (BBO), cesium lithium borate (CLBO), lithium niobate (LiNbO₃), lithium tantalite (LiTaO₃), potassium dihydrogen phosphate (KDP), and potassium titanyl phosphate (KTP). It is to be appreciated that one or more components of the thermally conductive enclosure 105 can be sized to accommodate one or more dimensions of the crystal. The NLO oven designs described herein can also accommodate or be modified to accommodate almost any sized cross section of crystal material. Although the examples shown and described assume a crystal having a rectangular cross-section, aspects of the disclosure include implementations in which this is not the case. The design of the thermally conductive enclosure 105 (and/or other components, such as the expandable attachment assembly 140 described in further detail below) may be modified for different crystal cross-sections, e.g., non-square rectangular cross-sections, cylindrical crystals, or multi-faceted crystals.

According to some embodiments, the thermally conductive enclosure 105 is configured such that it is in thermal contact with at least a portion of one longitudinal face 116 of the NLO crystal 115, as shown in FIG. 1A. As will be appreciated, the end faces 118 of the NLO crystal 115 are not covered or otherwise encapsulated by the thermally conductive enclosure 105, since these portions of the crystal are optically engaged with laser radiation used in nonlinear optical processes. Furthermore, in accordance with at least one embodiment, the NLO oven 100 is not configured to seal or otherwise encapsulate or thermally enclose around the NLO crystal for purposes of heating, as is the case for conventional crystal ovens. In some instances there may be an overall housing that includes several components (including the oven), such as optical fiber and optical components, and structural support, but it is to be appreciated that even within this environment, the oven 100 is open to “free space” (or open air) that includes incoming light beams. In accordance with at least one aspect, the oven 100 is configured such that heat loss around the crystal is minimal and conventional enclosures for thermal encasement are simply not necessary. The ovens described herein are configured to operate without a thermal enclosure, i.e., the oven does not need thermal insulation around it or in its immediate vicinity to maintain the temperature of the crystal at or above 250° C. This attribute reduces costs and allows for more design freedom when implementing the oven in frequency conversion applications. However, in some instances a thermal enclosure may still be used for various purposes, for example, to reduce power consumption and/or to stay within the power limits of the heating element.

In accordance with one embodiment, the thermally conductive enclosure 105 is configured with a recess 107 for the heating element 110, as shown in FIGS. 1A and 1B. In this example, the recess 107 is outlined by dotted lines, as it is hidden from view on the end and side views, respectively, of FIGS. 1A and 1B. As shown, the heating element 110 may be disposed in a recess 107 of a component (e.g., one of the L-shaped components in FIGS. 1A and 1B) of the thermally conductive enclosure 105. In some embodiments, the heating element 110 may be held in place by one or more components of the expandable attachment assembly 140. The recess 107 is sized to accommodate one or more dimensions of the heating element (e.g., length and width). The depth dimension of the recess 107 may be configured to accommodate the heating element 110 and to prevent shorting between electrical leads (not shown) and a surface or surfaces of the thermally conductive enclosure 105. The recess 107 is configured to allow for the heating element 110 to “nest” within the recess 107.

In accordance with at least one embodiment, the heating element 110 contains or otherwise includes a ceramic material. One non-limiting example of a suitable ceramic material is silicon nitride (SiN), and it is to be appreciated that other ceramic materials are also within the scope of this disclosure. The heating element 110 may also include one or more electrical leads that connect the heating element to a power supply and/or a controller (e.g., controller 170, described in further detail below). According to one embodiment, the heating element 110 is a ceramic heating element comprising internal electrical conductors encased in a heat conducting ceramic material.

According to at least one embodiment, the heating element 110 is configured to heat to a temperature of at least 250° C. inclusive. In some embodiments, the heating element 110 is configured to heat to a temperature of at least 400° C. inclusive, in other embodiments the heating element 110 is configured to heat to a temperature of at least 450° C. inclusive, and in yet other embodiments the heating element 110 heats to a temperature of 500° C. inclusive. In accordance with certain embodiments, the heating element 110 is configured to heat to a temperature in a range of 250° C. to 500° C. inclusive. Although higher temperatures, e.g., temperatures of at least 250° C. are described herein, it is to be appreciated that the heating element 110 can heat to lower temperatures as well, and has the ability to heat the NLO crystal 115 to any temperature between room temperatures (20° C.) and 500° C. inclusive.

In addition to the ability to heat to temperatures above 220° C., the heater is also of sufficient size to heat the crystal 115 via thermal conduction through one or more components of the thermally conductive enclosure 105. Heat generated by the heating element 110 is transferred to the crystal 115 through one or more components of the thermally conductive enclosure 105 to the opening 135 where the crystal 115 resides. In some embodiments, the heating element 110 has a length dimension or overall length L in the longitudinal direction that is less than the length of the longitudinal length (i.e., length of the longitudinal face 116) of the crystal 115. In some instances, the length L of the heating element 110 may be equal to or greater than the length of the crystal 115. In some embodiments, the heating element is sized to have a length dimension (L) of less than 10 mm, and in one embodiment the heating element has a length of about 7 mm.

In accordance with at least one embodiment, the NLO crystal is configured for non-critical phase matching at a temperature in a range of 250° C. to 500° C. inclusive. As mentioned above, phase matching is an additional benefit of operating at these higher temperatures.

According to some embodiments, the oven may include two heating elements. FIGS. 2A and 2B are simplified schematic representations of one non-limiting example of an NLO oven (labeled generally at 200) showing an end view of the optical axis and a side view of the longitudinal axis of the NLO crystal 215, respectively, that is heated by two heating elements 210, one being positioned in proximity to each end of the crystal 215. This configuration allows for a temperature gradient to be established along the longitudinal axis of the crystal, i.e., a thermal gradient oven configuration, as understood by one skilled in the art. It is to be appreciated that oven 200 also includes other features described herein, including a thermally conductive enclosure 205, an expandable attachment assembly, and a support structure.

In accordance with certain embodiments, and as shown in the end views (optical axis) of FIGS. 3 and 4, the NLO oven 100 also comprises a support structure 120. The support structure 120 is configured to support the thermally conductive enclosure 105. In some embodiments, the support structure 120 includes at least one plate or platform and is configured to provide a structural base for other components of the oven and functions to hold the oven in a fixed location. According to some embodiments, the support structure 120 is thermally isolated from the thermally conductive enclosure 105. The thermal isolation assists in keeping heat generated by the heating element 110 in a more localized area of the thermally conductive enclosure 105 around the crystal 115, thereby making it easier for the crystal 115 to maintain higher temperatures. This allows the thermally conductive enclosure 105 to have a relatively small thermal gradient for purposes of temperature control. The term thermally isolated (or substantially isolated) does not mean the complete absence of thermal conduction or complete insulation, but instead indicates that any thermal conduction that does occur is relatively inefficient (compared with a thermally conductive material) and likely will not substantially reduce the temperature of the thermally conductive enclosure 105 by redirecting generated heat (from heating element 110) to the support structure 120.

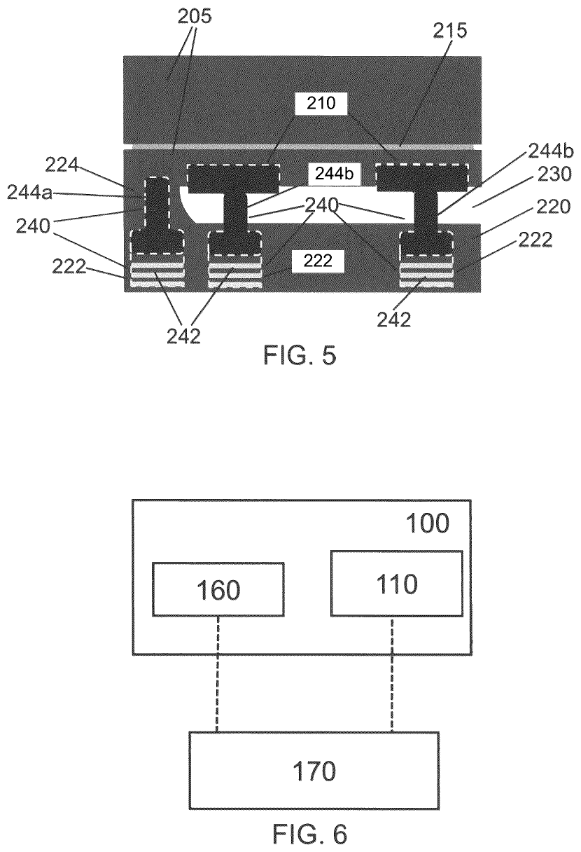

In accordance with certain embodiments, and as shown in FIGS. 3 and 4, there is an air space (or gas space) or gap 130 or separation that at least partially extends between the thermally conductive enclosure 105 and the support structure 120 that provides thermal separation between the two structures. The air gap 130 can extend between at least a portion of a bottom surface of the thermally conductive enclosure 105 and a top surface of the support structure 120. According to some embodiments, a lower or bottom portion of the thermally conductive enclosure 105 (e.g., a leg or other extension) can extend down and attach to the support structure 120, which interrupts this air gap 130 (e.g., see discussion regarding FIG. 5 below).

According to another embodiment, and as shown in FIG. 4, thermal isolation or separation between the thermally conductive enclosure 105 and the support structure 120 is provided by at least one thermally insulative device 125. As illustrated in FIG. 4, at least one thermally insulative device 125 is positioned between the support structure 120 and the thermally conductive enclosure 105. According to one embodiment, the thermally insulative device 125 is a ceramic ball, and some embodiments include two or more, e.g., three ceramic balls, are provided. The thermally insulative device 125 is hidden from the end view of FIG. 4, as indicated by the dotted lines. In this example, the ceramic balls fit into recesses (e.g., circular, cone-shaped, or V-grooves) of the thermally conductive enclosure 105 and the support structure 120.

In accordance with at least one aspect, the thermally insulative device 125 (e.g., ceramic balls) and the spring force exerted by the expandable attachment assembly 140 work in cooperation with each other to secure the thermally conductive enclosure 105 to the support structure 120 kinematically on the thermally insulative devices 125. This kinematic mounting or coupling is one technique for aligning different parts and as used herein is intended to refer to any of a variety of such techniques used to mechanically constrain the relative position of the thermally conductive enclosure 105 to the support structure 120, and to allow movement only in certain directions. For instance, the components of the thermally conductive enclosure 105 can expand at a different rate than the support structure 120, but the two structures can stay aligned with respect to one another. According to some embodiments, a ball and groove configuration is used. As will be appreciated, the theory of kinematic design requires perfectly rigid bodies that touch only at a point or points (e.g., point contacts).

According to certain embodiments, the NLO oven also comprises an expandable attachment assembly 140, examples of which are shown in FIG. 3 (showing an end view similar to that of FIG. 1A). The expandable attachment assembly 140 is configured such that the NLO crystal 115 is secured within the opening 135 of the thermally conductive enclosure 105 by a spring force exerted by the expandable attachment assembly 140. In accordance with one aspect, the expandable attachment assembly 140 allows for the NLO crystal 115 to thermally expand along one or more axes when heated, which prevents damage, such as cracking or other mechanical instability, to the crystal 115. The thermally conductive enclosure 105 is constructed from a material that has a different coefficient of thermal expansion (CTE) than a CTE of the NLO crystal 115, and the expandable attachment assembly 140 is configured to reduce stress on the NLO crystal 115 that occurs due to the difference in the coefficients of thermal expansion when the heating element 110 heats to a temperature in a range of 250° C. to 500° C. inclusive. The expandable attachment assembly 140 can also keep the NLO crystal 115 stable such that it maintains optical alignment during the heating process.

As described in further detail below, the expandable attachment assembly 140 includes one or more springs 142 that absorb tension exerted by the NLO crystal 115 as it expands upon being heated. Furthermore, as explained above, the material of the thermally conductive enclosure 105 and the material of the NLO crystal 115 expand by different amounts with temperature and the components of the expandable attachment assembly 140 allow for these expansion differences without inducing mechanical stresses on the crystal. In accordance with one aspect, the NLO crystal 115 is secured within the opening 135 by at least one spring 142 of the expandable attachment assembly 140. One or more longitudinal faces 116 of the NLO crystal 115 are held in contact with surfaces of the thermally conductive enclosure 105 under a spring force exerted by the expandable attachment assembly 140.

The expandable attachment assembly 140 comprises at least one spring 142. A non-limiting example of a spring 142 configuration is shown in FIG. 3, where the springs 142 are hidden from the end view shown in this figure. According to one embodiment, the support structure 120 includes a recess 122 for the spring 142 of the expandable attachment assembly 140. As shown in FIG. 3, the recess 122 is hidden, as indicated by dotted lines. Besides at least one spring 142, the expandable attachment assembly 140 may also comprise one or more screws or pins (non-limiting examples shown in FIG. 3 as 144), clamps, rods, dowel pins, etc. that attach or otherwise engage with one or more components (recesses, holes, threads, surfaces, etc.) of the thermally conductive enclosure 105 and the support structure 120 via frictional and spring forces.

FIG. 3 shows two non-limiting examples of how components of the expandable attachment assembly 140 can engage with the spring 142 and the enclosure 105. The left side of FIG. 3 shows an arrangement whereby at least a portion, e.g., a head, of a pin or screw 144 engages with the spring 142, and the tip of the pin or screw 144 engages with a lower portion of the thermally conductive enclosure 105. On the right side or FIG. 3, an arrangement is shown where a head of a pin or screw 144 engages with an upper or outer surface (and in this example at least partially resides within a recess of this surface) of the thermally conductive enclosure 105, and the tip of the pin or screw 144 engages with the spring 142. In some embodiments, the recess 122 of the support structure 120 may also include threads that the pin or screw may also engage with, and/or O-rings, gaskets, etc. may also be included. In both examples shown in FIG. 3, the pin or screw 144 is hidden from the end view, as indicated by the dotted lines. It is to be appreciated that the examples of the components of the expandable attachment assembly 140 shown in FIG. 3 are non-limiting and other configurations are also within the scope of this disclosure, including the use of mechanical plungers, such as spring or ball plungers.

In accordance with at least one embodiment, the placement of components of the expandable attachment assembly 120, including the spring 142, being positioned in the support structure 120 assists in keeping heat generated by the heating element 110 in a more localized area of the thermally conductive enclosure 105, which allows for the crystal 115 to achieve and maintain higher temperatures.

As part of the functionality of securing the crystal 115 in the opening 135 created by the components of the thermally conductive enclosure 105, the expandable attachment assembly 140 is configured to hold these components to one another. In some embodiments, the expandable attachment assembly 140 is also configured to hold the heating element 110 to the thermally conductive enclosure 105. At least one of the thermally conductive enclosure 105 and the support structure 120 include components or features (e.g., recesses, notches, holes, slots, tabs) that assist the expandable clamping assembly 140 in safely holding the NLO crystal 115.

Now turning to FIG. 5, a side view example is shown of a configuration where a support structure 220 is used in combination with a thermally conductive enclosure 205 that includes two heating elements (e.g., as in FIGS. 2A and 2B). As mentioned previously, having two heating elements positioned in proximity to each end 118 of the crystal allows for a temperature gradient to be established along the longitudinal axis of the crystal 215. In accordance with at least one embodiment, a thermal sink 224 extends between the thermally conductive enclosure 205 and the support structure 220. This feature allows for heat to deposit in a region in proximity to one end of the crystal 215, which assists in establishing or otherwise forming the thermal gradient. An air or gas space 230 at least partially extends between the thermally conductive enclosure 205 and the support structure 220.

An expandable attachment assembly 240 is also shown in FIG. 5. As with the embodiments discussed above in reference to FIG. 3, the expandable attachment assembly 240 is configured such that the NLO crystal 215 is secured within an opening of the thermally conductive enclosure 205 by a spring force exerted by the expandable attachment assembly 240, and includes one or more springs 242 that absorb tension exerted by the NLO crystal as it expands upon being heated. As also mentioned above, having the springs 242 positioned in the support structure 220 assists in keeping heat generated by the heating element 210 in amore localized area of the thermally conductive enclosure 205. The expandable attachment assembly 240 functions in a similar manner as described previously, e.g., it is configured to reduce stress on the NLO crystal 215 that occurs due to the difference in CTEs between the enclosure 205 and the crystal 215. In the side view shown in FIG. 5, the springs 242 are hidden from view, as indicated by the dotted lines, and are positioned within recesses 222 (the recesses 222 may include threads, O-rings, gaskets, as previously mentioned), which are also hidden in this view and indicated by the dotted lines.

The expandable attachment assembly 240 may also comprise one or more screws or pins (a non-limiting example is shown in FIG. 5 as 244), clamps, rods, dowel pints, etc. that attached or otherwise engage with one or more components (recesses, holes, threads, surfaces) of the thermally conductive enclosure 205 and the support structure 120 via frictional and spring forces. FIG. 5 shows one non-limiting embodiment of how a head of a pin or screw 244a engages with a spring 242, and a tip of the pin or screw 244a engages with a lower portion of the thermally conductive enclosure 205. Although not explicitly shown in FIG. 5, according to other embodiments, a head of a pin or screw can engage with an upper or outer surface of the thermally conductive enclosure 205, and the tip of the pin or screw engages with the spring 242.

According to some embodiments, and as shown in FIG. 5, the expandable attachment assembly 240 is also configured to hold the heating element 210 to the thermally conductive enclosure 205. In this example, a head of a pin or screw 244b engages with a spring 242, and a tip of the pin or screw 244b engages with a surface of the heating element 210. In some embodiments, a plate or other structure may be positioned in between the tip of the pin or screw 244b and the heating element 210, with the spring force being exerted through this structure.

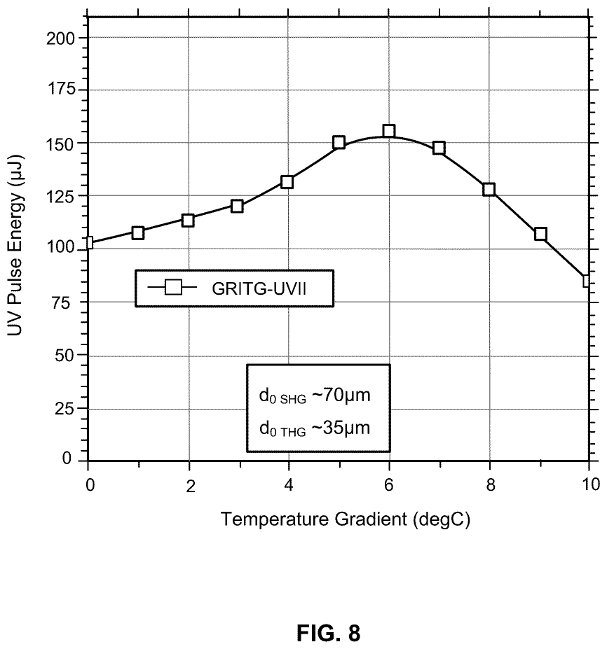

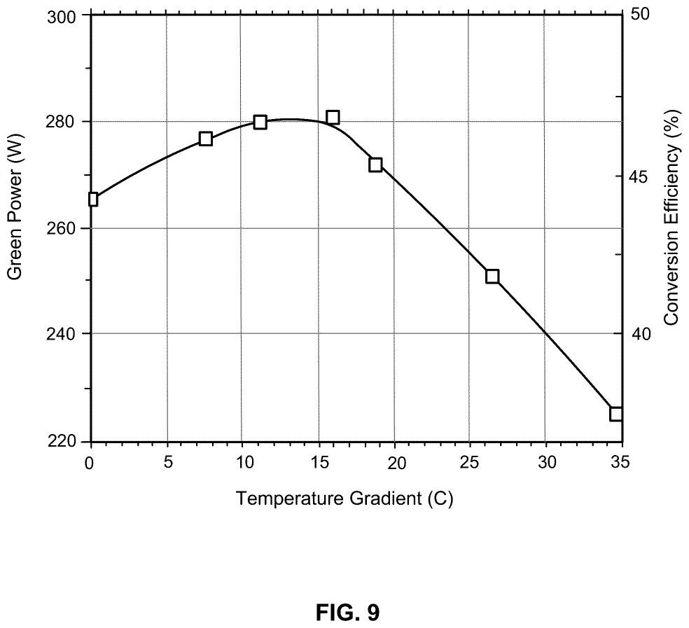

In accordance with various aspects, configuring the oven with two heaters and establishing a temperature gradient across the NLO crystal enhances performance of the frequency conversion system. This is shown in the graphs of FIGS. 8 and 9. FIG. 8 is a graph showing the relationship between UV pulse energy and a temperature gradient across the NLO crystal. As indicated, the UV pulse energy increases from about 100 microjoules (μJ) at zero (no temperature gradient) to about 150 μJ at a temperature gradient of about 6° C., after which the pulse energy decreases. This data was obtained using a ytterbium picosecond fiber laser. FIG. 9 is a graph showing the relationship between green laser power output (left y-axis), conversion efficiency (right y-axis) and a temperature gradient across the NLO crystal. As shown, laser power and conversion efficiency increased from about 265 watts (W) and about 44%, respectively, at zero (no temperature gradient) to about 280 W and about 47%, respectively, at a 13-14° C. temperature gradient. Conversion efficiency is improved because the introduction of the temperature gradient increases the spectral acceptance of the NLO crystal in applications where spectrally broadband laser beams are used.

In accordance with at least one embodiment, a temperature sensor 160 (see FIG. 3, hidden from the end view as indicated by dotted lines) is used to take temperature measurements and can be used in combination with a controller 170 (described in more detail below) to control the heating element 110. One or more components of the thermally conductive enclosure 105 can be configured to accommodate the temperature sensor 160, such as by having a recess for the temperature sensor to nest in. In some embodiments, the temperature sensor 160 is positioned in proximity to the NLO crystal 115. Heat generated by the heating element 110 is conducted to the NLO crystal 115 through one or more components of the thermally conductive enclosure 105 and is measured by the temperature sensor 160.

According to at least one embodiment, a controller 170 is used in combination with one or more components of the oven 100. An example is shown in the block diagram of FIG. 6, where a controller 170 is in communication with or is otherwise coupled to the temperature sensor 160 and the heating element 110 (e.g., via electrical leads) of the oven 100. For example, the controller 170 is configured to control an amount of heat produced by the heating element 110 and to receive temperature measurements from the temperature sensor 160. A predetermined target temperature can be input to the controller 170 by a user, or in some instances the controller 170 can determine the predetermined target temperature based on other inputs. The controller 170 can control the heating element 110 such that it continues to increase heat output until the target temperature is measured by the temperature sensor 160 and received by the controller 170. In accordance with one embodiment, the controller 170 and temperature sensor 160 have the ability to maintain the temperature at the temperature sensor to within 0.2° C. As will be appreciated, the controller 170 includes hardware (e.g., a computer) and software that may be used in controlling components of the system, including the heating element 110, as well as receiving information from components of the system, including the temperature sensor 160. Although oven 100 is described here in reference to FIG. 6, it is to be appreciated that oven 200 as described in reference to FIGS. 2A, 2B, and FIG. 5 may also be used in combination with a controller and temperature sensor in a similar manner. Two temperature sensors may be implemented, one for each heater.

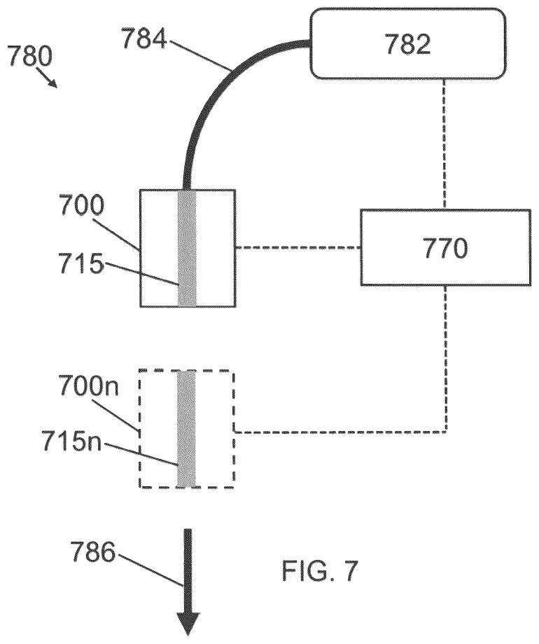

Turning now to FIG. 7, a simplified block diagram of a wavelength conversion system, indicated generally at 780 is shown, which may be used in implementing a wavelength conversion method in accordance with various embodiments. A laser light source 782 is provided that generates a laser light beam 784 at a first wavelength (e.g., a fundamental wavelength) and in some embodiments is propagated by an optical fiber, which is then passed through an NLO crystal 715 as previously described that converts the first wavelength to at least one second wavelength, emitted as light beam 786. System 780 also includes an oven 700 (e.g., oven 100 or 200) as described herein that is controlled by controller 770. The controller 770 also controls one or more components of the laser light source 782 (e.g., power supply, pumps for the laser, such as SM or MM laser diodes or fiber laser pumps).

As will be appreciated, the wavelength conversion system 780 can optionally include more than one NLO crystal (indicated in FIG. 7 by 715n with an associated oven indicated by 700n), such as for applications that require more than one NLO crystal to achieve the desired nonlinear frequency conversion.

Nonlinear frequency mixing occurs between different modes of the laser light beam 784 within the NLO crystal 715 (and optionally 700n, depending on the application). According to various embodiments, the nonlinear frequency mixing is a mixing operation selected from the group consisting of harmonic generation, sum frequency generation, difference frequency generation, optical parametric generation, optical parametric amplification, and optical parametric oscillation.

The laser light source 782 can comprise any one of a number of different laser sources, non-limiting examples of which are solid-state lasers, including fiber lasers, semiconductor lasers, and disk lasers, and gas lasers, such as excimer lasers. As will be appreciated, the laser light source 782 may include one or more optical devices, including lenses (e.g., collimating, focusing, field, condensing, etc.), reflective elements such as mirrors, beam splitters, and other optical or laser elements, including pumps sources, amplifiers (e.g., doped fiber amplifiers), multiplexers, couplers, circulators, filters (e.g., fiber Bragg gratings), optical isolators, power source(s), etc. The generated light can be CW, QCW, or pulsed, depending on the desired application.

One or more embodiments of the present invention include wavelength conversion methods. Certain of the methods comprise providing a laser light source (e.g., 782 of FIG. 7) that is configured to generate a laser light beam having a first wavelength, providing an oven (e.g., 700, 700n of FIG. 7) for an NLO crystal 715, 715n, positioning the NLO crystal 715,715n within the oven 700, 700n, heating the NLO crystal 715, 715n to a temperature of at least 250° C. inclusive, where the NLO crystal 715, 715n is configured to convert the first wavelength to at least one second wavelength, and directing the laser light beam though the NLO crystal.

In accordance with another embodiments, one or more of the NLO oven designs described herein can be used in combination with a hermetic enclosure. The primary function of the hermetic enclosure is to isolate the crystal from contamination, e.g., components that outgas. Non-limiting examples of components that outgas include the heating element 110 and the temperature sensor 160. To this end, the heating element 110 and/or temperature sensor 160 can be enclosed within a structure, such as a cylindrical box (e.g., tube-like structure) or other enclosure that surrounds these components and includes a seal to seal them in. The enclosure and seal are constructed from materials, such as metals, that are capable of withstanding high temperatures, e.g., 500° C. produced by the heating element 110. For example, in one embodiment the seal is constructed from copper.

In some embodiments, the crystal 115 and oven portions that surround the crystal (e.g., the thermally conductive enclosure 105) may be enclosed in a separate hermetically sealed optical enclosure. This served to protect the crystal from contamination.

The aspects disclosed herein in accordance with the present invention, are not limited in their application to the details of construction and the arrangement of components set forth in the following description or illustrated in the accompanying drawings. These aspects are capable of assuming other embodiments and of being practiced or of being carried out in various ways. Examples of specific implementations are provided herein for illustrative purposes only and are not intended to be limiting. In particular, acts, components, elements, and features discussed in connection with any one or more embodiments are not intended to be excluded from a similar role in any other embodiments.

Also, the phraseology and terminology used herein is for the purpose of description and should not be regarded as limiting. Any references to examples, embodiments, components, elements or acts of the systems and methods herein referred to in the singular may also embrace embodiments including a plurality, and any references in plural to any embodiment, component, element or act herein may also embrace embodiments including only a singularity. References in the singular or plural form are not intended to limit the presently disclosed systems or methods, their components, acts, or elements. The use herein of “including,” “comprising,” “having,” “containing,” “involving,” and variations thereof is meant to encompass the items listed thereafter and equivalents thereof as well as additional items. References to “or” may be construed as inclusive so that any terms described using “or” may indicate any of a single, more than one, and all of the described terms. In addition, in the event of inconsistent usages of terms between this document and documents incorporated herein by reference, the term usage in the incorporated reference is supplementary to that of this document; for irreconcilable inconsistencies, the term usage in this document controls. Moreover, titles or subtitles may be used in the specification for the convenience of a reader, which shall have no influence on the scope of the present invention.

Having thus described several aspects of at least one example, it is to be appreciated that various alterations, modifications, and improvements will readily occur to those skilled in the art. For instance, examples disclosed herein may also be used in other contexts. Such alterations, modifications, and improvements are intended to be part of this disclosure, and are intended to be within the scope of the examples discussed herein. Accordingly, the foregoing description and drawings are by way of example only.

What is claimed is:

1. An oven for a nonlinear optical (NLO) crystal, comprising:
a thermally conductive enclosure configured to define an opening for holding the NLO crystal and to thermally conduct heat between a heating element and the NLO crystal, the thermally conductive enclosure in thermal contact with at least a portion of the NLO crystal and the heating element configured to heat to a temperature of at least 250° C. inclusive;
a support structure configured to support the thermally conductive enclosure, the support structure thermally isolated from the thermally conductive enclosure; and
an expandable attachment assembly configured such that the NLO crystal is secured within the opening of the thermally conductive enclosure by a spring force exerted by the expandable attachment assembly.

2. The oven of claim 1, wherein an air space at least partially extends between the thermally conductive enclosure and the support structure.

3. The oven of claim 2, wherein the support structure includes a recess for a spring of the expandable attachment assembly.

4. The oven of claim 2, further comprising at least one thermally insulative device positioned between the support structure and the thermally conductive enclosure.

5. The oven of claim 2, wherein the thermally conductive enclosure is configured to thermally conduct heat between the NLO crystal and two heating elements, and the oven further comprises a thermal sink extending between the thermally conductive enclosure and the support structure.

6. The oven of claim 1, wherein the heating element is configured to heat to a temperature of at least 400° C. inclusive.

7. The oven of claim 1, wherein the heating element is configured to heat to a temperature in a range of 250° C. to 500° C. inclusive.

8. The oven of claim 1, wherein the thermally conductive enclosure is constructed from a material that has a coefficient of thermal expansion that is different from a coefficient of thermal expansion of the NLO crystal, and the expandable attachment assembly is configured to reduce stress on the NLO crystal that occurs due to the difference in the coefficients of thermal expansion when the heating element heats to a temperature in a range of 250° C. to 500° C. inclusive.

9. The oven of claim 1, further comprising a controller, the controller coupled to the heating element and configured to control an amount of heat produced by the heating element and to receive temperature measurements from a temperature sensor positioned in proximity to the NLO crystal.

10. The oven of claim 1, wherein the thermally conductive enclosure is constructed from aluminum.

11. The oven of claim 1, wherein the thermally conductive enclosure includes at least two components and is configured such that a gap exists between a first and a second component that are adjacent one another.

12. The oven of claim 1, configured to operate without a thermal enclosure.

13. The oven of claim 1, wherein the NLO crystal is configured for non-critical phase matching at a temperature in a range of 250° C. to 500° C. inclusive.

14. A method, comprising
providing an oven as described in claim 1.

15. A wavelength conversion method, comprising:
providing a laser light source configured to generate a laser light beam having a first wavelength;
providing an oven for a nonlinear optical (NLO) crystal, the oven including
a thermally conductive enclosure configured to define an opening for holding the NLO crystal and to thermally conduct heat between a heating element and the NLO crystal, and
a support structure configured to support the thermally conductive enclosure, the support structure thermally isolated from the thermally conductive enclosure;
positioning the NLO crystal within the opening of the oven;
heating the nonlinear optical (NLO) crystal to a temperature of at least 250° C. inclusive, the NLO crystal configured to convert the first wavelength to at least one second wavelength; and
directing the laser light beam through the NLO crystal.

16. The wavelength conversion method of claim 15, wherein heating includes heating the NLO crystal to a temperature in a range of 250° C. to 500° C. inclusive.

17. The wavelength conversion method of claim 15, further comprising providing the NLO crystal.

18. The wavelength conversion method of claim 17, wherein nonlinear frequency mixing occurs between different modes of the laser light beam having the first wavelength within the NLO crystal, and the nonlinear frequency mixing is a mixing operation selected from the group consisting of harmonic generation, sum frequency generation, difference frequency generation, optical parametric generation, optical parametric amplification, and optical parametric oscillation.

19. The wavelength conversion method of claim 15, further comprising measuring a temperature of the NLO crystal and controlling the heating element based on the temperature measurement.

20. The wavelength conversion method of claim 15, wherein the oven further includes an expandable attachment assembly configured such that the NLO crystal is secured within the opening of the thermally conductive enclosure by a spring force exerted by the expandable attachment assembly.
